(19) United States
(12) Patent Application Publication
(10) Pub. No.: US 2026/0262199 A1
(43) Pub. Date: Sep. 3, 2026

(54) LIQUID HEAT CONDUCTION MATERIAL, COMBINATION OF MEMBERS FOR PRODUCING HEAT CONDUCTION SHEET, HEAT CONDUCTION SHEET, HEAT DISSIPATING DEVICE, AND METHOD OF MANUFACTURING HEAT CONDUCTION SHEET

(71) Applicant: RESONAC CORPORATION, Tokyo (JP)

(72) Inventors: Mika KOBUNE, Tokyo (JP); Ricardo Mizoguchi Gorgoll, Tokyo (JP)

(21) Appl. No.: 19/431,637

(22) Filed: Dec. 23, 2025

Related U.S. Application Data
(63) Continuation of application No. 18/861,880, filed on Jul. 21, 2023.

(30) Foreign Application Priority Data
Jul. 22, 2022 (WO) PCT/JP2022/025828

(51) Int. Cl. H05K 7/20; H10W 40/70

(52) U.S. Cl. CPC H05K 7/20454; H05K 7/20463; H10W 40/70

(57) ABSTRACT

A liquid heat conduction material has a thermal conductivity that is greater than or equal to 5 W/(m·K). The liquid heat conduction material is for forming a liquid layer by applying the material to at least a part of a heat conduction layer. The heat conduction layer contains heat conductive particles.

### CROSS-REFERENCE TO RELATED APPLICATIONS

The present application is a continuation application of U.S. Ser. No. 18/861,880, filed on Oct. 31, 2024, which is a National Stage entry of PCT/JP2023/026893, filed Jul. 21, 2023, which claims priority to PCT/JP2022/028528, filed on Jul. 22, 2022. The entire disclosure of each of the above applications is incorporated herein by reference.

### TECHNICAL FIELD

The present invention relates to a liquid heat conduction material, a combination of members for producing a heat conduction sheet, a heat conduction sheet, a heat dissipating device, and a method of manufacturing the heat conduction sheet.

In recent years, the amount of heat generation increases due to high density of mounting density of the wiring and the electronic component in the semiconductor package using a multilayered wiring board, and the amount of heat generation per unit area increases due to the high integration of semiconductor devices. There is a growing demand for increased heat dissipation from semiconductor packages.

In general, a heat dissipating device for dissipating heat by closely adhering a heat conduction grease or a heat conduction sheet between a heat generating body such as a semiconductor package and a heat dissipating body such as aluminum or copper is simply used. In general, heat conduction sheets are superior to heat conduction greases in workability when assembling the heat dissipating device.

In recent years, chips of CPU (central processing unit) tend to be larger in area by multi-core and multi-chip. Further, there is a tendency to lower the pressure of pressure bonding between CPU that is a heat generating body and a heat dissipating body. Therefore, the heat conduction sheet is required to have flexibility at the time of pressure bonding. Further, the heat conduction sheet is required to be excellent in the thermal conductivity so that even if the heat conduction sheet becomes thick due to the chip level difference, the heat conduction sheet has a low thermal resistance.

As the heat conduction sheet, it is also known a resin sheet filled with heat conduction filler. As a resin sheet excellent in the thermal conductivity filled with the heat conductive filler, various resin sheets have been proposed in which inorganic particles with a high thermal conductivity are selected as the heat conductive filler, and further the inorganic particles are oriented perpendicularly to the sheet surface.

For example, the heat conduction sheet (see, for example, Patent Literature 1) in which a heat conductive filler (boron nitride) is oriented in a direction substantially perpendicular to the sheet surface, and the heat conduction sheet (see, for example, Patent Literature 2) having the structure that carbon fibers dispersed in a gel-like substance is oriented perpendicular to the sheet surface has been proposed.

### CITATION LIST

### Patent Literature

Patent Literature 1: Japanese Patent Application Laid-Open (JP-A) No. 2002-26202
Patent Literature 2: Japanese Patent Application Laid-Open (JP-A) No. 2001-250894

### SUMMARY OF INVENTION

### Technical Problem

In Patent Documents 1 and 2, a method of suppressing thermal resistance by orienting a heat conduction filler, a carbon fiber, or the like in a direction perpendicular to the sheet surface is considered. In order to cope with the increase in heat generation due to the high performance and large size of semiconductors, it is desired to further reduce the thermal resistance of heat conduction sheets. Therefore, it is preferable to reduce the thermal resistance by taking into account methods other than the orientation of a heat conduction filler, a carbon fiber, or the like contained in the heat conduction sheet.

It is an object of the present invention to provide a liquid heat conduction material capable of reducing thermal resistance by applying it to a heat conduction layer such as a heat conduction sheet, a combination of members for producing a heat conduction sheet capable of producing a heat conduction sheet with a low thermal resistance, a heat conduction sheet with a low thermal resistance, a heat dissipating device provided with this heat conduction sheet and a method of manufacturing a heat conduction sheet capable of manufacturing a heat conduction sheet with a low thermal resistance.

### Solution to Problem

Specific means for addressing the above problem include the following aspects.
<1> A liquid heat conduction material having a thermal conductivity of 5 W/(m·K) or more, for forming a liquid layer by applying the material to at least a part of a heat conduction layer containing heat conductive particles.
<2> The liquid heat conduction material according to <1>, wherein the material comprises a heat conductive filler and a resin component.
<3> The liquid heat conduction material according to <2>, wherein a particle size of the heat conductive filler is from 0.1 μm to 50 μm.
<4> The liquid heat conduction material according to <2> or <3>, wherein the resin component comprises a thermosetting resin component.
<5> The liquid heat conduction material according to any one of <1> to <4>, wherein a viscosity at 25° C. is 4000 Pa·s or less.
<6> A combination of members for producing a heat conduction sheet comprising: the liquid heat conduction material according to any one of <1> to <5>, and a heat conduction material containing heat conductive particles.
<7> A combination of members for producing a heat conduction sheet comprising: a liquid heat conduction material containing a metal component and a heat conduction material containing heat conductive particles.
<8> The combination of members for producing a heat conduction sheet according to <7>, wherein a melting point of the metal component is 50° C. or less.
<9> A heat conduction sheet, comprising:
   a heat conduction layer including a heat conduction material containing heat conductive particles, and
   a liquid layer which is located on at least a part of a main surface of the heat conduction layer and contains a first liquid heat conduction material which is the liquid heat conduction material according to any one of claims 1 to 5, or a second liquid heat conduction material which is a liquid heat conduction material containing a metal component.
<10> The heat conduction sheet according to <9>,
   wherein the heat conductive particles includes at least one kind of graphite particles (A) selected from the group consisting of scale-like particles, ellipsoidal particles and rod-like particles,
   wherein in a case of scale-like particles, a plane direction of the particle is oriented in a thickness direction of the heat conduction layer, and in a case of ellipsoidal particles or rod-like particles, a long axis direction of the particle is oriented in the thickness direction of the heat conduction layer.
<11> The heat conduction sheet according to <9> or <10>, wherein a maximum thickness of the liquid layer is from 0.5 μm to 20 μm.
<12> The heat conduction sheet according to any one of <9> to <11>, wherein the liquid layer contains the first liquid heat conduction material and the liquid layer is curable by heating.
<13> A heat dissipating device, comprising a heat generating body, a heat dissipating body, and the heat conduction sheet according to any one of <9> to <11> interposed between the heat generating body and the heat dissipating body,
   wherein in the heat conduction layer, the liquid layer is located on at least a part of a main surface located on the heat generating body side or a main surface located on the heat dissipating body side.
<14> A heat dissipating device, comprising a heat generating body, a heat dissipating body, and the heat conduction sheet according to <12>, which is interposed between the heat generating body and the heat dissipating body and includes an adhesive layer formed by curing the liquid layer,
   wherein in the heat conduction layer, the adhesive layer is located on at least a part of a main surface located on the heat generating body side or a main surface located on the heat dissipating body side.
<15> A method of manufacturing a heat conduction sheet which manufactures the heat conduction sheet according to any one of <9> to <12>, comprising:
   a step of preparing a composition containing the heat conductive particles, a step of forming the heat conduction layer using the composition, and a step of forming a liquid layer on at least a part of a main surface of the heat conduction layer.
<16> A method of manufacturing a heat conduction sheet which manufactures the heat conduction sheet according to <10>, comprising:
   a step of preparing a composition containing the graphite particles (A),
   a step of forming the composition into a sheet,
   a step of producing a layered body of the sheets,
   a step of slicing a side end face of the layered body, and
   a step of forming a liquid layer on at least a part of a main surface of a sliced sheet which is obtained by slicing and corresponds to a heat conduction layer.

### Advantageous Effects of Invention

In the present disclosure, a liquid heat conduction material capable of reducing thermal resistance by applying it to a heat conduction layer such as a heat conduction sheet, a combination of members for producing a heat conduction sheet capable of producing a heat conduction sheet with a low thermal resistance, a heat conduction sheet with a low thermal resistance, a heat dissipating device provided with this heat conduction sheet and a method of manufacturing a heat conduction sheet capable of manufacturing a heat conduction sheet with a low thermal resistance can be provided.

### BRIEF DESCRIPTION OF DRAWINGS

FIG. 1 is a schematic configuration view of a heat conduction sheet, which is an embodiment of the present invention.

FIG. 2 is a schematic cross-sectional view of a heat dissipating device, which is an embodiment of the present invention, when a heat generating body is a semiconductor chip and a heat dissipating body is a heat spreader.

FIG. 3 is a view showing the state of the interface by image analysis in Examples 1 to 4 and Comparative Examples 1 to 2.

### DESCRIPTION OF EMBODIMENTS

Hereinafter, modes for carrying out the present invention will be described in detail. However, the present invention is not limited to the following embodiments. In the following embodiments, the constituent elements (including element steps and the like) are not essential unless otherwise specified. The same applies to numerical values and ranges thereof, and does not limit the present invention.

In the present disclosure, the term “step” includes, in addition to steps independent of other steps, such steps as long as the purpose of the step is achieved even if it cannot be clearly distinguished from other steps.

In the present disclosure, those numerical ranges that are expressed with “to” each denote a range that includes the numerical values stated before and after “to” as the minimum value and the maximum value, respectively.

In a set of numerical ranges that are stated stepwise in the present disclosure, the upper limit value or the lower limit value of a numerical range may be replaced with the upper limit value or the lower limit value of other numerical range. Further, in a numerical range stated in the present disclosure, the upper limit value or the lower limit value of the numerical range may be replaced with a value indicated in Examples.

In the present disclosure, each component may contain plural kinds of substances that correspond to the indicated component. In a case in which there are plural kinds of substances that correspond to the component in a composition, the indicated content ratio or content of the component in the composition means, unless otherwise specified, the total content ratio or content of the plural kinds of substances existing in the composition.

In the present disclosure, each component may contain plural kinds of particles that correspond to the indicated component. In a case in which there are plural kinds of particles that correspond to the component in a composition, the indicated particle size of the component in the composition means, unless otherwise specified, a value determined for a mixture of the plural kinds of particles existing in the composition.

In the present disclosure, the term “layer” or “film” includes, in addition to the case where the region is entirely formed, that when the region where the layer or the film is present is observed, it is formed in only a part of the region.

In the present disclosure, the term “layered” refers to stacking layers, two or more layers may be combined, and two or more layers may be removable.

### [Liquid Heat Conduction Material]

A liquid heat conduction material of the present disclosure has a thermal conductivity of 5 W/(m·K) or more, and is the material for forming a liquid layer by applying the material to at least a part of a heat conduction layer containing heat conductive particles.

In the present disclosure, a liquid heat conduction material means a heat conduction material that is liquid at at least a part of the temperature range from 0° C. to 50° C.

In the present disclosure, thermal conductivity can be measured by the xenon flash (Xe-flash) method.

It is difficult to reduce a resistance (also referred to as “contact thermal resistance”) due to a gap generated by contact between a heat conduction sheet and an adherend such as a heat generating body or a heat dissipating body that contacts the heat conduction sheet is difficult to reduce by the configuration of the heat conductive particles contained in the heat conduction sheet or the composition of the heat conduction sheet. The liquid heat conductive material of the present disclosure is a material for forming a heat conduction sheet or the like having a liquid layer by being applied to at least a part of a heat conduction layer containing heat conductive particles. When the heat conduction layer on which the liquid layer is formed are heat-compression bonded to an adherend such as a heat generating body or a heat dissipating body, the liquid layer flows between the heat conduction layer and the adherend. Thereby, a gap between the heat conduction sheet and the adherend (for example, a gap resulting from unevenness of the heat conduction sheet) is filled with the flowed liquid layer, so that the heat conduction sheet and the adherend can be closely attached via the liquid layer. As a result, the contact thermal resistance is significantly reduced. Furthermore, since the thermal conductivity of the liquid heat conduction material is 5 W/(m·K) or more, the decrease in thermal conductivity of the heat conduction sheet caused by disposing the liquid layer on the heat conduction layer is suppressed, and an increase in the thermal resistance of the heat conduction sheet is suppressed.

Contact thermal resistance is also likely to occur when there are unevennesses on a surface of an adherend such as a heat generating body or a heat dissipating body. In this case, it is difficult to reduce the thermal resistance by adjusting the orientation of the heat conductive filler contained in the heat conduction sheet. On the other hand, by using the liquid heat conduction material of the present disclosure, the heat conduction sheet and the adherend having unevennesses on a surface can be brought into close contact via the liquid layer. At this time, the liquid layer fills a gap generated when the heat conduction sheet and the adherend are heat-compression bonded (for example, a gap resulting from unevenness of the adherend), thereby significantly reducing contact thermal resistance.

The liquid heat conduction material of the present disclosure preferably contains a heat conductive filler and a resin component. The resin component may contain a component that is liquid at 25° C.

Examples of the heat conductive filler include metal-containing particles and non-metal particles that have excellent thermal conductivity. The heat conductive filler may be, for example, a filler having a thermal conductivity of 10 W/(m·K) or more. The heat conductive filler may be insulating or electrically conductive.

The heat conductive filler may be at least one type of particles selected from the group consisting of silver, aluminum oxide, aluminum hydroxide, magnesium oxide, beryllium oxide, boron nitride, aluminum nitride, silicon nitride, silicon carbide, silicon dioxide, aluminum fluoride, calcium fluoride, zinc oxide, diamond, gallium, indium and tin.

The heat conductive filler contained in the liquid heat conduction material may be of one type alone or a combination of two or more types.

The liquid heat conduction material of the present disclosure may or may not contain low melting point metal particles having a melting point of 200° C. or less.

The particle size of the heat conductive filler may be 0.1 μm to 50 μm, may be from 0.2 μm to 20 μm or may be from 0.5 μm to 10 μm, from the viewpoint of excellent thermal conductivity and further reducing a gap between an adherend and the heat conduction sheet.

The particle size (D50) of the heat conductive filler is measured using a laser diffraction particle size distribution device (for example, “Microtrack series MT3300” manufactured by Nikkiso Co., Ltd.) adapted to a laser diffraction/scattering method, and when a mass cumulative particle size distribution curve is drawn from the small particle size side, D50 corresponds to the particle size at which the mass accumulation is 50%.

The resin component may be a non-curable resin component, or may be a curable resin component such as a thermosetting or photocurable resin component. From the viewpoint of adhesion to the adherend during curing, thermal conductivity, or the like, it is preferable that the resin component contains a thermosetting resin component. The resin component may contain one type of resin component, or may contain two or more types of resin components.

As the non-curable resin component, a non-curable resin component that is liquid at 25° C. is preferable, and a liquid silicone compound, a liquid (meth)acrylic compound, a liquid polyester compound, or the like is more preferable.

As the thermosetting resin component, a thermosetting resin component that is liquid at 25° C. is preferable, and a liquid epoxy compound, a curable liquid silicone compound, a curable liquid (meth)acrylic compound, or the like is more preferable.

The content ratio of the heat conductive filler contained in the liquid conduction material is, for example, from the viewpoint of the balance between the heat conductivity and adhesion, preferably from 70% by mass to 98% by mass, more preferably from 75% by mass to 95% by mass, and still more preferably from 80% by mass to 93% by mass, with respect to the total amount of the liquid conduction material.

The content ratio of the resin component contained in the liquid conduction material is, for example, from the viewpoint of the balance between the heat conductivity and adhesion, preferably from 2% by mass to 30% by mass, more preferably from 5% by mass to 25% by mass, and still more preferably from 7% by mass to 20% by mass, with respect to the total amount of the liquid conduction material.

The total content ratio of the heat conductive filler and the resin component contained in the liquid heat conduction material may be from 80% by mass to 100% by mass, or may be from 90% by mass to 100% by mass, with respect to the total amount of the liquid heat conduction material.

The liquid heat conduction material may or may not contain another component other than the heat conductive filler or the resin component.

In the liquid heat conduction material of the present disclosure, the viscosity at 25° C. is preferably 4000 Pa·s or less, may be from 0.001 Pa·s to 3000 Pa·s, or may be from 10 Pa·s to 2000 Pa·s. By having the viscosity at 25° C. of 4000 Pa·s or less, the liquid layer tends to flow easily between the heat conduction layer and the adherend, and therefore a gap between the heat conduction sheet and the adherend tends to be easily and suitably filled with the liquid layer.

The viscosity at 25° C. is measured at a shear rate of 5.0 s⁻¹ using a rheometer at 25° C. In particular, the “viscosity” is measured as shear viscosity at a temperature of 25° C. using a rotational shear viscometer equipped with a cone plate (diameter 40 mm, cone angle 0°).

### [Combination of Members for Producing a Heat Conduction Sheet]

A combination 1 of members for producing a heat conduction sheet of the present disclosure includes the liquid heat conduction material according to any one of claims 1 to 5, and a heat conduction material containing heat conductive particles. The heat conduction material is a material for forming the heat conduction layer of the heat conduction sheet. A heat conduction sheet can be obtained by applying a liquid heat conduction material to at least a part of a heat conduction layer made of a heat conduction material to form a liquid layer.

The heat conduction material preferably contains heat conduction particles and is solid at 25° C.

The heat conduction material contains heat conduction particles. The heat conduction particles are preferably at least one type of particles selected from graphite, carbon, silver, aluminum oxide, aluminum hydroxide, magnesium oxide, beryllium oxide, boron nitride, aluminum nitride, silicon nitride, silicon carbide, silicon dioxide, aluminum fluoride, calcium fluoride, and zinc oxide. From the viewpoint of thermal conductivity when formed into a heat conduction layer, the heat conduction particles are preferably graphite particles, carbon particles, and boron nitride particles, and more preferably graphite particles.

The heat conduction particles is preferably at least one selected from the group consisting of scale-like particles, ellipsoidal particles, and rod-like particles, and more preferably at least one graphite particles (hereinafter, also referred to as “graphite particles (A)”) selected from the group consisting of scale-like particles, ellipsoidal particles, and rod-like particles. When the heat conduction particles are graphite particles (A), it is preferable that, in a case of scale-like particles, a plane direction of the particle is oriented in a thickness direction, and in a case of ellipsoidal particles or rod-like particles, a long axis direction of the particle is oriented in the thickness direction.

Hereinafter, a preferable aspect, in which the heat conductive particles are graphite particles (A), will be described.

It is preferable that, in a case of scale-like particles, a plane direction of the particle is oriented in a thickness direction, and in a case of ellipsoidal particles or rod-like particles, a long axis direction of the particle is oriented in the thickness direction. It is more preferable that, in a case of scale-like particles, a six-membered ring plane in crystal is oriented in a plane direction of the particle in a case of scale-like particles, is oriented in a long axis direction of the particle in a case of ellipsoidal particles, and is oriented in a long axis direction in a case of rod-like particles. A six-membered ring plane is a plane in which a six-membered ring is formed in a hexagonal system, and means a (0001) crystal plane.

It is more preferable that a shape of the graphite particles (A) is scale-like. By selecting a scale-like graphite particles, the thermal conductivity tends to be further improved. This reason can be considered, for example, for the scale-like graphite particles to be more easily oriented in a predetermined direction in the heat conduction material.

Whether the six-membered ring plane in the crystal is oriented in the plane direction of scale-like particles, the long axis direction of ellipsoidal particles or the long axis direction of rod-like particles, it can be confirmed by X-ray diffraction measurement. The orientation direction of the six-membered ring plane in the crystal of the graphite particle (A) is specifically confirmed by the following method.

At first, a sample sheet for measurement in which the plane direction of scale-like particles, the long axis direction of ellipsoidal particles or the long axis direction of rod-like particles in the graphite particles (A) is oriented along the sheet direction is prepared. As a specific preparation method of the measurement sample sheet, for example, the following method may be mentioned.

A mixture of a resin and the graphite particles (A) in an amount of 10% by volume or more with respect to the resin is sheeted. The “resin” used herein is not particularly limited as long as a material that does not exhibit a peak that interferes with X-ray diffraction and that can form a sheet. Specifically, an amorphous resin having a cohesive force as a binder can be used, such as acrylic rubber, NBR (acrylonitrile butadiene rubber), SIBS (styrene-isobutylene-styrene copolymer), or the like.

The sheet of this mixture is pressed so as to be 1/10 or less of the original thickness, and a plurality of pressed sheets are layered to form a layered body. The operation of further crushing this layered body to the thickness of 1/10 or less is repeated three times or more to obtain a sample sheet for measurement. By this operation, in a case of scale-like particles, a plane direction of the particle is oriented in a plane direction of the sample sheet, in a case of ellipsoidal particles, a long axis direction of the particle is oriented in the plane direction of the sample sheet, and in a case of rod-like particles, a long axis direction of the particle is oriented in the plane direction of the sample sheet.

The X-ray diffraction measurement is performed to the surface of the measurement sample sheet prepared as described above. The height H₁ of the peak corresponding to the (110) plane of graphite appearing around 2θ=77° and the height H₂ of the peak corresponding to the (002) plane of graphite appearing around 2θ=27° are measured. In the measurement sample sheet prepared in this manner, the value obtained by dividing H₁ by H₂ is 0 to 0.02.

From this, it can be seen that “the six-membered ring plane in the crystal of the graphite particle (A) is oriented in the plane direction of scale-like particles, the long axis direction of ellipsoidal particles or the long axis direction of rod-like particles” means that X-ray diffraction measurement is performed on the surface of the sheet including the graphite particle (A), and the value obtained by dividing the peak height corresponding to the (110) plane of the graphite particle (A) appearing around 2θ=77° by the peak height corresponding to the (002) plane of the graphite particle (A) appearing near 2θ=27° is 0 to 0.02.

In the present disclosure, X-ray diffraction measurement is performed under the following conditions.
Device: Bruker AXS KK “D8DISCOVER”
X-ray source: CuKα wavelength 1.5406 nm, 40 kV, 40 mA
Step (measurement step size): 0.01°
Step time: 720 sec

Herein, “in a case of scale-like particles, a plane direction of the particle is oriented in a thickness direction of the heat conduction material, and in a case of ellipsoidal particles or rod-like particles, a long axis direction of the particle is oriented in the thickness direction of the heat conduction material” means that the angle (hereinafter also referred to as “orientation angle”) between a plane direction in a case of scale-like particles, a long axis direction in a case of ellipsoidal particles or a long axis direction in a case of rod-like particles, and the surface (main surface) of the heat conduction material is 60° or more. The orientation angle is preferably 80° or more, more preferably 85° or more, and still more preferably 88° or more.

The orientation angle is an average value when a cross section of the heat conduction material is observed with SEM (scanning electron microscope), and the angle (orientation angle) between a plane direction in a case of scale-like particles, a long axis direction in a case of ellipsoidal particles or a long axis direction in a case of rod-like particles, and the surface (main surface) of the heat conduction material for arbitrary 50 graphite particles (A) is measured.

The particle size of the graphite particles (A) is not particularly limited. The average particle size of the graphite particles (A) is preferably a half of the average thickness to the average thickness of the heat conduction material. When the average particle size of the graphite particles (A) is a half or more of the average thickness of the heat conduction material, an efficient heat conduction path tends to be formed in the heat conduction material, and the thermal conductivity tends to be improved. When the average particle size of the graphite particles (A) is equal to or less than the average thickness of the heat conduction material, the protrusion of the graphite particles (A) from the surface of the heat conduction material is suppressed, and the adhesion of the surface of the heat conduction material tends to be excellent.

A method of manufacturing a heat conduction material so as to be oriented in the plane direction of scale-like particles, the long axis direction of ellipsoidal particles or the long axis direction of rod-like particles, is not particularly limited and for example, the method described in JP-A No. 2008-280496 can be used. Specifically, a method can be used in which sheets are prepared using a composition, the sheets are layered to prepare a layered body, and the side end face of the layered body is sliced (for example, at an angle of 0° to 30° with respect to the normal line extending from the main surface of the layered body) (hereinafter, also referred to as the “layered slice method”).

In the case of using the above-mentioned layered slice method, the particle size of the graphite particles (A) used as the raw material, as a mass average particle size, is preferably a half times or more of the average thickness of the heat conduction material, and may exceed the average thickness. The reason why the particle size of the graphite particles (A) used as the raw material may exceed the average thickness of the heat conduction material is, for example, even if the graphite particles (A) having a particle size exceeding the average thickness of the heat conduction material are included, because the graphite particles (A) are sliced to form the heat conduction material, the graphite particles (A) do not project from the surface of the heat conduction material as a result. Further, when the whole graphite particles (A) are sliced in this manner, a large number of graphite particles (A) penetrating in the thickness direction of the heat conduction material are generated, extremely efficient heat conduction paths are formed, and the heat conductivity tends to be further improved.

When using the layered slice method, the particle size of the graphite particles (A) used as the raw material, as a mass average particle size is more preferably from 1 to 5 times of the average thickness of the heat conduction material. When the mass average particle size of the graphite particles (A) is 1 or more times the average thickness of the heat conduction material, a more efficient heat conduction path is formed, and the thermal conductivity is further improved. When the mass average particle size of the graphite particles (A) is 5 times or less the average thickness of the heat conduction material, the area of the graphite particles (A) to the surface can be prevented from being too large, and the decrease in the adhesion can be suppressed.

The mass average particle size of the graphite particles (A) (D50) is measured by using a laser diffraction type particle size distribution device adapted to laser diffraction scattering method (e.g., manufactured by Nikkiso Co., Ltd. “Microtrac Series MT3300”), and when the weight cumulative particle size distribution curve is drawn from the small particle size side, it corresponds to the particle size at which the weight cumulative becomes 50%.

The heat conduction material may contain particles other than scale-like particles, ellipsoidal particles or rod-like particles as graphite particles, and may contain spherical graphite particles, artificial graphite particles, exfoliated graphite particles, acid-treated graphite particles, expanded graphite particles, carbon fiber flakes or the like.

As the graphite particles (A), scale-like particles are preferable, and, from the viewpoint of easily obtaining a scaly having a high degree of crystallinity and a large particle size, scale-like expanded graphite particles obtained by pulverizing sheeted expanded graphite are preferable.

The content ratio of the graphite particles (A) in the heat conduction material is, for example, from the viewpoint of the balance between the thermal conductivity and the adhesion is preferably from 15% by volume to 50% by volume, more preferably from 20% by volume to 45% by volume, and still more preferably from 25% by volume to 40% by volume.

When the content ratio of the graphite particles (A) is 15% by volume or more, the thermal conductivity tends to be further improved. When the content ratio of the graphite particles (A) is 50% by volume or less, the decrease in the adhesiveness and the adhesion tends to be suppressed.

When the heat conduction material contains graphite particles other than scale-like particles, ellipsoidal particles or rod-like particles, the content ratio of the entire graphite particles is preferably included in the above range.

The content ratio of the graphite particles (A) (% by volume) is determined by the following Formula.

$$Content ratio ( \% by volume ) of graphite particles ( A ) = \{ ( Aw / Ad ) / ( ( Aw / Ad ) + ( Xw / Xd ) ) \} \times 100$$

$$Aw : mass composition ( \% by mass ) of graphite particles ( A )$$

$$Xw : mass composition ( \% by mass ) of other optional ingredients$$

$$Ad : density of graphite particles ( A ) ( in the present specification , Ad is calculated with 2.1 )$$

$$Xd : density of other optional ingredients$$

The content ratio of the spherical graphite particles, artificial graphite particles, acid-treated graphite particles, or carbon fibers in the heat conduction layer may be each independently from 0% by volume to 10% by volume, may be from 0% by volume to 5% by volume, or may be from 0% by volume to 1% by volume.

Graphite particles (A): carbon fibers, which is a mass ratio of the graphite particles (A) and the carbon fibers in the heat conduction layer may be from 100:0 to 100:30, may be from 100:0 to 100:20, or may be from 100:0 to 100:10. Since carbon fibers are generally hard, by using a smaller amount of carbon fibers than graphite particles (A), the flexibility of the heat conduction sheet can be ensured and an increase in contact thermal resistance tends to be suppressed.

<Component (B) that is Liquid at 25° C.>

The heat conduction material may contain a component (B) that is liquid at 25° C. (hereinafter, also referred to as “liquid component (B)”). In the present disclosure, “liquid at 25° C.” means a substance that shows fluidity and viscidity at 25° C. and has a viscosity as a measure of viscidity is from 0.0001 Pa·s to 1000 Pa·s at 25° C. In the present disclosure, “viscosity” is defined as a value measured at a shear rate of 5.0 s⁻¹ using a rheometer at 25° C. In particular, the “viscosity” is measured as shear viscosity at a temperature of 25° C. using a rotational shear viscometer equipped with a cone plate (diameter 40 mm, cone angle) 0°.

The viscosity of the liquid component (B) at 25° C. is preferably from 0.001 Pa·s to 100 Pa·s, or more preferably from 0.01 Pa·s to 10 Pa·s.

The liquid component (B) is not particularly limited as long as it is liquid at 25° C., and is preferably a high molecular compound (polymer). Examples of the liquid component (B) include polybutene, polyisoprene, polysulfide, acrylonitrile rubber, silicone rubber, hydrocarbon resin, terpene resin, and acrylic resin. Among these, from the viewpoint of heat resistance, the liquid component (B) preferably contains polybutene. The liquid component (B) may be used alone or in combination of two or more.

Herein, polybutene refers to a polymer obtained by polymerizing isobutene or normal butene. It also includes polymers obtained by copolymerizing isobutene and normal butene. It refers to a polymer having a structural unit represented by “—CH₂—C(CH₃)₂—” or “—CH₂—CH(CH₂CH₃)—” as the structure. It is also sometimes called polyisobutylene. The polybutene only needs to contain the above structure, and other structures are not particularly limited.

Examples of the polybutene include a butene homopolymer and a copolymer of butene and another monomer component. Examples of the copolymer with another monomer component include a copolymer of isobutene and styrene or a copolymer of isobutene and ethylene. The copolymer may be a random copolymer, a block copolymer, or a graft copolymer.

Examples of the polybutene include NOF Corporation's “NOF Polybutene™ Emawet (registered trademark)” JXTG Nippon Oil & Energy Corporation's “Nippon Oil Polybutene” JXTG Nippon Oil & Energy Corporation's “Tetrax” JXTG Nippon Oil & Energy Corporation's “Himol” and Tomoe Engineering Co., Ltd.'s “Polyisobutylene”.

It is thought that the liquid component (B) mainly functions as, for example, a stress reliever and a tackifier, which have excellent heat resistance and humidity resistance. Further, by using it in combination with a hot melt agent (D) described below, there is a tendency that cohesive force, and fluidity during heating can be more improved.

The content ratio of the liquid component (B) in the heat conduction material is preferably from 10% by volume to 55% by volume, more preferably from 15% by volume to 50% by volume, and still more preferably from 20% volume to 50% by volume from the viewpoint of further increasing adhesive strength, adhesion, sheet strength, hydrolysis resistance, or the like.

When the content ratio of the liquid component (B) is 10% by volume or more, adhesiveness and adhesion tend to be improved. When the content ratio of the liquid component (B) is 55% by volume, there is a tendency that decreases in sheet strength and thermal conductivity can be effectively suppressed.

### <Acrylic Acid Ester Polymer (C)>

The heat conduction material may contain an acrylic ester polymer (C). It is thought that the acrylic ester polymer (C) mainly functions as, for example, a tackifier and an elasticity-imparting agent that allows the thickness to be restored in order to follow warpage.

As the acrylic acid ester-based polymer (C), for example, an acrylic acid ester-based polymer (so-called acrylic rubber) obtained by copolymerizing butyl acrylate, ethyl acrylate, acrylonitrile, acrylic acid, glycidyl methacrylate, 2-ethylhexyl acrylate, or the like as a main raw material component and, if necessary, methyl acrylate, or the like, is preferably used. The acrylic ester polymer (C) may be used alone or in combination of two or more.

The weight average molecular weight of the acrylic ester polymer (C) is preferably from 100,000 to 1,000,000, more preferably from 250,000 to 700,000, and still more preferably from 400,000 to 600,000. When the weight average molecular weight is 100,000 or more, film strength tends to be excellent, and when it is 1,000,000 or less, flexibility tends to be excellent.

The weight average molecular weight can be measured by gel permeation chromatography using a standard polystyrene calibration curve.

The glass transition temperature (Tg) of the acrylic acid ester polymer (C) is preferably 20° C. or lower, more preferably from −70° C. to 0° C., and still more preferably from −50° C. to −20° C. When the glass transition temperature is 20° C. or lower, flexibility and adhesiveness tend to be excellent.

The glass transition temperature (Tg) can be calculated from the tan & derived from dynamic viscoelasticity measurement by tension.

The acrylic ester polymer (C) may be present in the entire heat conduction material by internal addition, or may be localized on a surface by applying or impregnating it on the surface. In particular, applying it on one side or impregnating it on one side is preferable because strong tackiness can be imparted to only one side, resulting in a sheet with good handling properties.

In the heat conduction layer, the content ratio of the acrylic ester polymer (C) is preferably from 3% by volume to 25% by volume, more preferably from 5% by volume to 20% by volume, and still more preferably from 7% by volume to 15% by volume.

### <Hot Melt Agent (D)>

The heat conduction material may contain a hot melt agent (D). The hot melt agent (D) has the effect of improving the strength of the heat conduction layer and improving the fluidity during heating.

Examples of the hot melt agent (D) include an aromatic petroleum resin, a terpene phenol resin, and a cyclopentadiene petroleum resin. Further, the hot melt agent (D) may be a hydrogenated aromatic petroleum resin or a hydrogenated terpene phenol resin. The hot melt agent (D) may be used alone or in combination of two or more.

Among them, when polybutene is used as the liquid component (B), the hot melt agent (D) preferably contains at least one selected from the group consisting of a hydrogenated aromatic petroleum resin and a hydrogenated terpene phenol resin. These hot melt agents (D) have high stability and excellent compatibility with polybutene, so they tend to be able to achieve better thermal conductivity, flexibility, and handleability when forming a heat conduction material.

Commercially available hydrogenated aromatic petroleum resins include, for example, “Alcon” by Arakawa Chemical Co., Ltd. and “Imarv” by Idemitsu Kosan Co., Ltd. Furthermore, examples of commercially available hydrogenated terpene phenol resins include “Clearon” manufactured by Yasuhara Chemical Co., Ltd. Commercially available cyclopentadiene petroleum resins include, for example, “Quinton” manufactured by Nippon Zeon Co., Ltd. and “Marcarez” manufactured by Maruzen Petrochemical Co., Ltd.

The hot melt agent (D) is solid at 25° C. and preferably has a softening temperature of from 40° C. to 150° C. When a thermoplastic resin is used as the hot melt agent (D), the softening fluidity during thermocompression bonding is improved, and as a result, adhesion tends to be improved. Further, when the softening temperature is 40° C. or higher, cohesive force can be maintained near room temperature, and as a result, it becomes easier to obtain the necessary sheet strength and tends to be excellent in handleability. When the softening temperature is 150° C. or less, the softening fluidity during thermocompression bonding becomes high, and as a result, adhesion tends to improve. The softening temperature is more preferably from 60° C. to 120° C. Note that the softening temperature is measured by the ring and ball method (JIS K 2207:1996).

The content ratio of the hot melt agent (D) in the heat conduction material is preferably from 3% by volume to 25% by volume, more preferably from 5% by volume to 20% by volume, and still more preferably from 5% by volume to 15% by volume, from the viewpoint of improving adhesive strength, adhesion, sheet strength, or the like.

When the content ratio of the hot melt agent (D) is 3% by volume or more, adhesive strength, heat fluidity, sheet strength, or the like tend to be sufficient, and when the content ratio is 25% by volume or less, there is a tendency that flexibility is sufficient and handling properties and thermal cycle resistance are excellent.

### <Antioxidant (E)>

The heat conduction material may contain an antioxidant, for example, for the purpose of imparting thermal stability at a high temperature. Examples of the antioxidant (E) include a phenolic type antioxidant, a phosphorus type antioxidant, an amine type antioxidant, a sulfur type antioxidant, a hydrazine type antioxidant, an amide type antioxidant and the like. The antioxidant (E) may be appropriately selected depending on the temperature conditions used, or the like, and a phenolic antioxidant is more preferable. The antioxidant (E) may be used alone or in combination of two or more.

Commercially available phenolic antioxidants include, for example, ADEKA STAB AO-50, ADEKA STAB AO-60, and ADEKA STAB AO-80 manufactured by ADEKA Corporation.

The content ratio of the antioxidant (E) in the heat conduction material is not particularly limited, and is preferably from 0.1% by volume to 5% by volume, more preferably from 0.2% by volume to 3% by volume, and still more preferably from 0.3% by volume to 1% by volume. When the content ratio of the antioxidant (E) is 0.1% by volume or more, a sufficient antioxidant effect tends to be obtained. When the content ratio of the antioxidant (E) is 5% by volume or less, the strength of the heat conduction material tends to be prevented from decreasing.

### <Other Ingredients>

The heat conduction material may contain other ingredients other than the graphite particles (A), the liquid component (B), the acrylic ester polymer (C), the hot melt agent (D), or the antioxidant (E) depending on the purpose. For example, the heat conduction material may include a flame retardant for the purpose of imparting flame retardancy. The flame retardant is not particularly limited, and can be appropriately selected from commonly used flame retardants. Examples thereof include a red phosphorus based flame retardant and a phosphoric acid ester based flame retardant can be mentioned. Among them, a phosphoric acid ester based flame retardant is preferable from the viewpoint of excellent safety and improved adhesion due to plasticizing effect.

As the red phosphorus based flame retardants, in addition to pure red phosphorus particles, those provided with various coatings for the purpose of improving safety or stability, or those made into a masterbatch may be used. Specific examples thereof include Nova Red, Nova Excel, Nova Cell, Nova Pellet (all trade names) manufactured by RIN KAGAKU KOGYO Co., Ltd., and the like.

Examples of the phosphoric acid ester based flame retardant include an aliphatic phosphoric acid ester such as trimethyl phosphate, triethyl phosphate, or tributyl phosphate; an aromatic phosphate ester such as triphenyl phosphate, tricresyl phosphate, cresyl diphenyl phosphate, trixylenyl phosphate, cresyl di 2,6-xylenyl phosphate, tris(t-butylated phenyl) phosphate, tris(isopropylated phenyl) phosphate, or triaryl isopropylated phosphate; an aromatic condensed phosphoric acid ester such as resorcinol bisdiphenyl phosphate, bisphenol A bis(diphenyl phosphate), or resorcinol bisdixylenyl phosphate.

Among these, bisphenol A bis(diphenyl phosphate) is preferable from the viewpoint of being excellent in hydrolysis resistance and excellent in the effect of improving the adhesion by a plasticizing effect.

The content ratio of the flame retardant in the heat conduction material is not limited and may be used in an amount that flame retardancy is exhibited, preferably on the order 30% by volume or less, and from the viewpoint of suppressing the deterioration of the heat resistance due to the flame retardant component exuding to a surface of the heat conduction layer, preferably 20% by volume or less.

### [Combination 1 of Members for Producing a Heat Conduction Sheet]

A combination 2 of members for producing a heat conduction sheet of the present disclosure includes a liquid heat conduction material containing a metal component and a heat conduction material containing heat conductive particles. A heat conduction sheet can be obtained by applying a liquid heat conduction material containing a metal component to at least a part of a heat conduction layer composed of a heat conduction material to form a liquid layer.

The preferable form of the heat conduction material in combination 2 of the members for producing a heat conduction sheet of the present disclosure is the same as the preferable form of the heat conduction material in combination 1 of the members for producing a heat conduction sheet of the present disclosure described above.

The combination 2 of members for producing a heat conduction sheet of the present disclosure is materials for forming a heat conduction sheet provided with a liquid layer by applying a liquid heat conduction material containing a metal component to at least a part of the heat conduction layer made of a heat conduction material. When the heat conduction layer on which the liquid layer is formed is heat-compressed with an adherend such as a heat generating body or a heat dissipating body, the liquid layer flows between the heat conduction layer and the adherend. As a result, a gap between the heat conduction sheet and the adherend is filled with the liquid layer, so that the heat conduction sheet and the adherend can be brought into close contact with each other via the liquid layer. As a result, contact thermal resistance is significantly reduced. Furthermore, since the liquid layer contains a metal component, the liquid layer has excellent thermal conductivity, and therefore, an increase in thermal resistance of the heat conduction sheet is suppressed.

### (Liquid Heat Conduction Material Containing Metal Component)

A liquid heat conduction material containing a metal component refers to a heat conduction material containing a metal component that becomes liquid at at least a part of the temperature range from 0° C. to 50° C. The thermal conductivity of the liquid heat conduction material containing a metal component is preferably 5 W/(m K) or more, more preferably 10 W/(m K) or more, and still more preferably 30 W/(m K).

The liquid heat conduction material containing a metal component may be a material consisting of a liquid metal component, or may be a material consisting of a liquid metal component and another component.

The content rate of the metal component contained in the liquid heat conduction material may be from 50% by mass to 100% by mass, may be from 70% by mass to 100% by mass, or may be from 90% by mass to 100% by mass, with respect to the total amount of the liquid heat conduction material.

The melting point of the aforementioned metal component is preferably 50° C. or less, more preferably 45° C. or lower, and still more preferably from 0° C. to 40° C.

Examples of the aforementioned metal components include gallium, indium, tin, and the like. Among these, a metal component containing gallium is preferable.

### [Heat Conduction Sheet]

The heat conduction sheet of the present disclosure includes a heat conduction layer including a heat conduction material containing heat conductive particles, and a liquid layer which is located on at least a part of a main surface of the heat conduction layer and contains a first liquid heat conduction material which is the liquid heat conduction material of the present disclosure, or a second liquid heat conduction material which is a liquid heat conduction material containing a metal component.

The preferable form of the first liquid heat conduction material is the same as the preferable form of the aforementioned liquid heat conduction material. The preferable form of the second liquid heat conduction material is the same as the liquid heat conduction material containing a metal component in the aforementioned combination 2 of members for producing a heat conduction sheet.

In the heat conduction sheet of the present disclosure, unevenness may exist on the surface that brings into contact with an adherend. At this time, most of the thermal resistance originates from the resistance (contact thermal resistance) caused by a gap generated by contact between the heat conduction sheet and an adherend such as a heat generating body or a heat dissipating body that contacts the heat conduction sheet. In the heat conduction sheet of the present disclosure, the liquid layer containing the first liquid heat conduction material or the second liquid heat conduction material is disposed on at least a part of a main surface of the heat conduction layer, so that when the heat conduction sheet and an adherend such as a heat generating body or a heat dissipating body are heat-compression bonded, the liquid layer flows due to heat, pressure, or the like. As the liquid layer flows, a gap generated when the heat conduction sheet and the adherend are heat-compression bonded (for example, a gap resulting from unevenness of the heat conduction sheet) is filled with the liquid layer. Thereby, the heat conduction sheet and the adherend can be brought into close contact with each other while reducing a gap between the heat conduction sheet and the adherend, so that the contact thermal resistance is significantly reduced.

Contact thermal resistance is also likely to occur when there are unevenness on the surface of an adherend such as a heat generating body or a heat dissipating body. In this case, it is difficult to reduce the thermal resistance by adjusting the orientation of the heat conductive filler and the like contained in the heat conduction sheet. On the other hand, by using the heat conduction sheet of the present disclosure, it is possible to bring the heat conduction sheet and an adherend having unevenness on the surface into close contact via the liquid layer. At this time, a gap generated when the heat conduction sheet and the adherend are heat-compression bonded (for example, a gap resulting from unevenness of the heat conduction sheet) is filled with the liquid layer, which significantly reduces the contact thermal resistance.

The average thickness of the heat conduction layer is not particularly limited and can be appropriately selected depending on the purpose. The thickness of the heat conduction layer can be appropriately selected depending on the specifications of the semiconductor package used. As the thickness decreases, the thermal resistance tends to decrease, and as the thickness increases, the warpage followability tends to improve. The average thickness of the heat conduction layer may be from 20 μm to 3000 μm, from the viewpoint of thermal conductivity and adhesion, preferably from 30 μm to 500 μm, and more preferably 50 μm to 400 μm.

The average thickness of the heat conduction layer is determined using an electron microscope. By observing the cross section of the object to be measured, the thickness is measured at three random locations, and the thickness is given as the arithmetic mean value.

In the heat conduction sheet of the present disclosure, the liquid layer only needs to be located on at least a part of a main surface of the heat conduction layer, and the liquid layer may be located on the entire main surface, or a part of the main surface (for example, a portion that brings into contact with an adherend such as a heating element or a heat radiating element).

In the heat conduction layer, the liquid layer may be located on one main surface, or the liquid layer may be located on two main surfaces.

The maximum thickness of the liquid layer is preferably from 0.5 μm to 50 μm, more preferably from 0.5 μm to 30 μm, and still more preferably from 0.5 μm to 20 μm. When the maximum thickness of the liquid layer is 0.5 μm or more, a gap between the adherend and the heat conduction sheet tends to be further reduced and the contact thermal resistance can be further reduced. When the maximum thickness of the liquid layer is 50 μm or less, there is a tendency that the thermal conductivity of the heat conduction sheet is excellent, and leakage of the liquid layer to the outside when the adherend and the heat conduction sheet are brought into contact can be suppressed.

The maximum thickness of the heat conduction layer and the maximum thickness of the liquid layer may be measured by observing the cross section of the measurement target using an electron microscope. Alternatively, the maximum thickness of the heat conduction layer may be measured using a micrometer. The maximum thickness of the heat conduction layer and the maximum thickness of the heat conduction sheet including the liquid layer are measured using a micrometer, and the maximum thickness of the liquid layer may be determined by subtracting the maximum thickness of the conduction layer from the maximum thickness of the heat conduction sheet.

When liquid layers are formed on the two main surfaces of the heat conduction layer, the maximum thickness of the liquid layer means the maximum value of the total thickness of the liquid layers formed on the two main surfaces.

When the liquid layer includes the first liquid heat conduction material, the liquid layer may be curable or may be curable by heating. When it can be cured by heating, for example, the first liquid heat conduction material preferably contains the aforementioned thermosetting resin component that is liquid at 25° C.

The heat conduction sheet may have a protective film on at least one side, and preferably has a protective film on both sides. This can protect the adhesive side of the heat conduction sheet.

As the protective film, for example, resin films such as polyethylene, polyester, polypropylene, polyethylene terephthalate, polyimide, polyether imide, polyether naphthalate, methyl pentene, and the like, coated paper, coated cloth, and metal foils such as aluminum are used. These protective films may be used alone or in combination of two or more as a multilayer film. The protective film is preferably surface-treated with a silicone-based or silica-based release agent.

The use of the heat conduction sheet is not particularly limited. When the semiconductor chip is the heat generating body and the heat spreader is the heat dissipating body, the heat conduction sheet of the present disclosure is particularly suitable as a heat conduction sheet (TIM1; Thermal Interface Material 1) that interposes a semiconductor chip and a heat spreader.

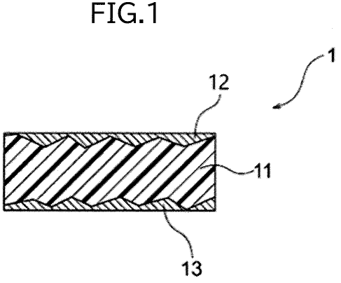

An embodiment of the heat conduction sheet will be described using FIG. 1. The heat conduction sheet of the present disclosure is not limited to the following embodiments.

The heat conduction sheet 1 shown in FIG. 1 includes a heat conduction layer 11 and liquid layers 12 and 13, with the liquid layer 12 located on one main surface of the heat conduction layer 11, and the liquid layer 13 located on the other main surface of the heat conduction layer 11.

As shown in FIG. 1, the two main surfaces of the heat conduction sheet 1 may be provided with the liquid layers 12, 13 to reduce unevenness. By providing the liquid layers 12, 13 on the main surfaces of the heat conduction layer 11, the unevenness of the heat conduction layer 11 can be filled with the liquid layers 12, 13, and when the heat conduction sheet 1 is brought into contact with an adherend, the unevenness of the surface of the adherend can also be filled with the liquid layers 12, 13.

### [Method of Manufacturing Heat Conduction Sheet]

A method of manufacturing a heat conduction sheet is not particularly limited as long as it can obtain a heat conduction sheet having the above configuration. The method of manufacturing a heat conduction sheet includes a step of preparing a composition containing the heat conductive particles (also referred to as a “preparation step”), and a step of forming the heat conduction layer using the composition (also referred to as a “formation step”) and a step of forming an liquid layer on at least a part of a main surface of the heat conduction layer (also referred to as an “liquid layer forming step”).

### <Preparation Step>

In the preparation step, a composition containing the heat conductive particles and optional other components is prepared. The method of blending each component is not particularly limited, and any method may be used as long as each component can be mixed uniformly.

### <Formation Step>

In the formation step, the heat conduction layer is formed using a composition containing the heat conductive particles and optional other components. For example, the heat conduction layer may be formed by forming the aforementioned composition into a sheet shape.

### <Liquid Layer Forming Step>

The liquid layer forming step may be any method that can form a liquid layer on at least a part of a main surface of the heat conduction layer, and is not particularly limited. For example, the first liquid heat conduction material or the second liquid heat conduction material may be applied to at least a part of a main surface of the heat conduction layer.

In the method of a heat conduction sheet, from the viewpoint of high thermal conductivity of the heat conduction sheet, it is preferable to manufacture a heat conduction sheet in which the heat conduction particles are the aforementioned graphite particles (A). Examples of methods of manufacturing a heat conduction sheet containing graphite particles (A) include the following methods.

In one embodiment, the method of manufacturing a heat conduction sheet includes a step of preparing a composition containing the graphite particles (A) and optional other components (the aforementioned preparation step), a step of forming the composition into a sheet to obtain a sheet (part of the aforementioned formation step, also referred to as “sheet forming step”), a step of producing a layered body of the sheets (part of the aforementioned formation step, also referred to as the “layered body producing step”), a step of slicing a side end face of the layered body (part of the aforementioned formation step, also referred to as the “slicing step”), and a step of forming a liquid layer on at least a part of a main surface of the sliced sheet (corresponding to the heat conduction layer) obtained by slicing (the aforementioned liquid layer forming step).

The method of manufacturing a heat conduction sheet may further include a step of laminating the heat conduction sheet by attaching a protective film to it after the liquid layer forming step (also referred to as the “lamination step”).

By manufacturing a heat conduction sheet by such a method, an efficient heat conduction path is easily formed, and therefore a heat conduction sheet with excellent high thermal conductivity and adhesion tends to be obtained.

### <Preparation Step>

In the preparation step, a composition containing graphite particles (A) and optional other components (for example, low melting point metal component, component (B) that is liquid at 25° C., acrylic acid ester polymer (C), hot melt agent (D), antioxidant (E), or other ingredients) is prepared. The method of blending each component is not particularly limited, and any method may be used as long as each component can be mixed uniformly. Alternatively, the composition may be prepared by obtaining a commercially available composition. For details on the preparation of the composition, reference can be made to paragraph of JP-A No. 2008-280496.

### <Sheet Forming Step>

The sheet forming step may be performed by any method as long as the composition obtained in the previous step can be formed into a sheet, and is not particularly limited. For example, it is preferable to carry out using at least one forming method selected from the group consisting of rolling, pressing, extrusion, and coating. For details of the sheet forming step, reference can be made to paragraph of JP-A No. 2008-280496.

### <Layered Body Producing Step>

The layered body producing step is a step to forming a layered body of sheets obtained in the previous step. The layered body may be a form in which a plurality of independent sheets are sequentially stacked, may be a form in which one sheet is folded or may be a form in which one sheet is rolled. For details of the layered body producing step, reference can be made to paragraphs to of JP-A No. 2008-280496.

### <Slicing Step>

The slicing step, when the side end face of the layered body obtained in the previous step can be sliced, may be any method, and is not particularly limited. From the viewpoint that a very efficient heat conduction path is formed by the graphite particles (A) penetrating in the thickness direction of the heat conduction sheet and the thermal conductivity is further improved, it is preferable to slice by the thickness of 2 times or less of the mass average particle size of the graphite particles (A). For details of the slicing step, reference can be made to paragraph of JP-A No. 2008-280496.

### <Liquid Layer Forming Step>

The liquid layer forming step may be any method that can form a liquid layer on at least a part of a main surface of the sliced sheet (corresponding to the heat conduction layer) obtained by slicing, and is not particularly limited. For example, the first liquid heat conduction material or the second liquid heat conduction material may be applied to at least a part of a main surface of the heat conduction layer.

### <Lamination Step>

The lamination step is not particularly limited and may be any method as long as the heat conduction sheet obtained in the liquid layer forming step can be attached to the protective film.

### [Heat Dissipating Device]

A heat dissipating device of the present disclosure is a device including a heat generating body, a heat dissipating body, and the heat conduction sheet of the present disclosure interposed between the heat generating body and the heat dissipating body, and in the heat conduction layer, the liquid layer is located on at least a part of a main surface located on the heat generating body side or a main surface located on the heat dissipating body side. It is preferable that the liquid layer is located on each of at least a part of a main surface located on the heat generating body side and at least a part of a main surface located on the heat dissipating body side, and it is more preferable that the liquid layer is located on each of on a region facing the heat generating body in a main surface located on the heat generating body side and a region facing the heat dissipating body in a main surface located on the heat dissipating body side.

Examples of the heat generating body include a semiconductor chip, a semiconductor package, a power module, and the like. Examples of the heat dissipating body include a heat spreader, a heat sink, a water cooling pipe, and the like.

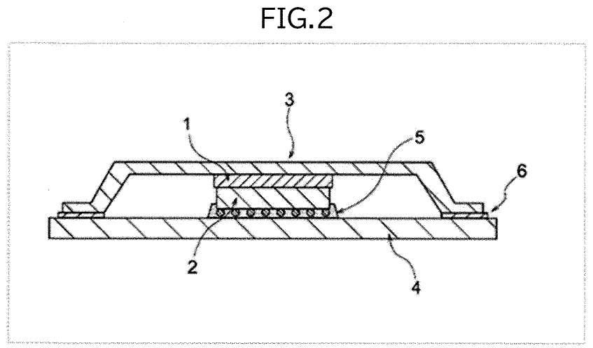

Hereinafter, an example of the heat dissipating device will be described in more detail using FIG. 2. A heat dissipating device using a semiconductor chip as a heat generating body and a heat spreader as a heat dissipating body will be described. A semiconductor chip and a heat spreader are examples of a heat generating body and a heat dissipating body, respectively, and the present disclosure is not limited thereto. The heat conduction sheet 1 is used with one side in close contact with the semiconductor chip 2 and the other side in close contact with the heat spreader 3. The semiconductor chip 2 is fixed to the substrate 4 using an underfill material 5, and the heat spreader 3 is fixed to the substrate 4 by a sealing material 6, and the adhesion between the heat conduction sheet 1, the semiconductor chip 2, and the heat spreader 3 is improved by pressing. Note that it is not necessary that one heat conduction sheet 1 has one heat generating body and one heat dissipating body. For example, a plurality of semiconductor chips 2 may be provided for one heat conduction sheet 1, one semiconductor chip 2 may be provided for a plurality of heat conduction sheets 1, and a plurality of semiconductor chips 2 may be provided for a plurality of heat conduction sheets 1. The liquid layer is located on a main surface of the heat conduction sheet 1 on the semiconductor chip 2 side and on the other main surface of the heat conduction sheet 1 on the heat spreader 3 side. For example, in the heat conduction sheet 1 shown in FIG. 1, the liquid layer 13 is located on a main surface of the heat conduction sheet 1 on the semiconductor chip 2 side, and the liquid layer 12 is located on the other main surface of the heat conduction sheet 1 on the heat spreader 3 side. Furthermore, the liquid layer 13 may be in contact with the semiconductor chip 2, and the liquid layer 12 may be in contact with the heat spreader 3.

The heat dissipating device includes the heat conduction sheet of the present disclosure disposed between a heat generating body and a heat dissipating body. Since the heat generating body and the heat dissipating body are layered via the heat conduction sheet, heat from the heat generating body can be efficiently conducted to the heat dissipating body. Efficient heat conduction is possible, thereby the lifespan of the heat dissipating device is improved, and the heat dissipating device that functions stably even during long-term use can be provided.

The temperature range which can particularly suitably use the heat conduction sheet may be, for example, −10° C. to 150° C., may be −10° C. to 100° C., or may be −10° C. to 80° C. For this reason, suitable examples of the heat generating body include semiconductor packages, displays, LEDs, electric lights, automotive power modules, and industrial power modules.

Examples of the heat dissipating body include a heat sink using aluminum or copper fins or plates, an aluminum or copper block connected to a heat pipe, an aluminum or copper block in which a cooling liquid is circulated by a pump, and a Peltier element and an aluminum or copper block equipped with the same.

The heat dissipating device is constructed by bringing each surface of the heat conduction sheet into contact with the heat generating body and the heat dissipating body. The method of bringing the heat generating body into contact with one side of the heat conduction sheet and the method of bringing the heat dissipating body into contact with the other side of the heat conduction sheet is not particularly limited as long as they can be fixed in a sufficiently close state.

For example, the method that the heat conduction sheet is disposed between the heat generating body and the heat dissipating body, and fixed with a jig that can pressurize to about 0.05 MPa to 1 MPa, and the heat generating body is heated in this state, or they are heated to about 80° C. to 200° C. in an oven or the like, can be mentioned. Another method that a press machine capable of heating and pressing at 80° C. to 200° C. and 0.05 MPa to 1 MPa, can be mentioned. The preferred pressure range for this method is 0.10 MPa to 1 MPa, and the preferred temperature range is 100° C. to 180° C. Excellent adhesion tends to be obtained by setting the pressure to 0.10 MPa or higher or the heating temperature to 100° C. or higher. Furthermore, when the pressure is 1 MPa or less or the heating temperature is 180° C. or less, the reliability of adhesion tends to be further improved. These reason is considered to be that it is possible to prevent the heat conduction sheet from being excessively compressed and becoming thinner, and from causing excessive distortion or residual stress in a surrounding member.

The heat conduction sheet disposed between the heat generating body and the heat dissipating body is not particularly limited as long as it is the above-mentioned heat conduction sheet. For example, the heat conduction sheet shown in FIG. 1 may be disposed between the heat generating body and the heat dissipating body.

When using the heat conduction sheet 1 shown in FIG. 1, by heating and pressurizing the heat conduction sheet 1 disposed between the heat generating body and the heat dissipating body, the liquid layers 12 and 13 located on the main surfaces of the heat conduction sheet 1 flow. A gap generated when the heat conduction sheet 1 and the heat generating body and the heat dissipating body are heat-compression bonded, is filled with the liquid layer which flows. Thereby, a gap between the heat conduction sheet and the adherend is reduced.

For example, when the liquid layer can be cured by heating using a first liquid heat conduction material containing a thermosetting resin component, the liquid layer flows by heat-compression bonding to fill a gap between the heat conduction sheet and the adherend, and the thermosetting resin component is cured by heating. Thereby, the heat conduction sheet and the adherend can be brought into close contact via an adhesive layer formed by the curing of the liquid layer.

The heat conduction sheet may have a ratio (compression ratio) of the reduced thickness after compression with respect to its initial thickness before being disposed between the heat generating body and the heat dissipating body and being compressed, of from 1% to 35%.

In addition to a clip, a jig such as a screw or a spring may be used for fixing, and it is preferable to further fix with commonly used means such as an adhesive in order to maintain close contact.

At the interface between the heat generating body and the heat conduction sheet and at the interface between the heat dissipating body and the heat conduction sheet, the void ratio calculated as the ratio of the area of the gas region with respect to the area of the measurement region is preferably from 0% to 20.0%, and more preferably from 0% to 15.0%. Thereby, a gap generated when the heat conduction sheet and the heat generating body or heat dissipating body are heat-compression bonded (for example, a gap resulting from unevenness of the heat conduction sheet and a gap resulting from unevenness of the heat generating body or heat dissipating body) is reduced. As a result, it is assumed that the contact thermal resistance is significantly reduced.

In the present disclosure, it is preferable that the void ratio satisfies the aforementioned numerical range in both the main surface side of the heat conduction layer where the liquid heat conduction material is located and the main surface side of the heat conduction layer where the liquid heat conduction material is not located.

In the present disclosure, the void ratio at the interface can be determined as follows. First, using an ultrasonic image diagnostic device (for example, Insight-300, manufactured by Insight Co., Ltd.), the adhesion state at the interface is observed under the condition of a reflection method and 35 MHz. The ratio of the area of the non-adhered gas region may be calculated, and the void ratio (%) at the interface may be calculated based on the following formula.

$$Void ratio ( \% ) at interface = 100 \times ( area of gas region / area of measurement region )$$

The numerical range of the void ratio at the interface can be adjusted by adjusting, for example, the viscosity of the liquid heat conduction material at 25° C., the amount of the liquid heat conduction material applied to the heat conduction layer, the compression ratio of the heat conduction sheet, or the like.

### EXAMPLES

Hereinafter, the present invention will be described in more detail with reference to Examples, but the present invention is not limited to these Examples.

### Example 1 to Example 4

The following materials were put into a kneader (Moriyama Co., Ltd., DS3-SGHM-E type pressurized double-arm kneader) so that the mixing ratio (volume %) was as shown in Table 1, and kneaded at a temperature of 150° C., a composition was obtained.

### <Graphite Particles (A)>

(A)-1: Scale-like expanded graphite particles (manufactured by Showa Denko Materials co., Ltd. “HGF-L”, mass average particle size: 270 μm, by a method using X-ray diffraction measurement described above, it was confirmed that the six-membered ring face in the crystal is oriented in the plane direction of the scale-like particles.)

### <Liquid Component (B)>

(B)-1: Isobutene/Normal Butene Copolymer (NOF Corporation “NOF Polybutene Copolymer™. Emawet (registered trademark), grade 30N”)
(B)-2: Isobutene homopolymer (Nippon Oil Co., Ltd. “Tetrax 6T”)

### <Acrylic Acid Ester Polymer (C)>

(C)-1: Acrylic ester copolymer resin (butyl acrylate/ethyl acrylate/acrylonitrile/acrylic acid copolymer, weight average molecular weight: 530,000, Tg=−39° C.)

### <Hot Melt Agent (D)>

(D)-1: Hydrogenated petroleum resin (Arakawa Chemical Co., Ltd. “Alcon P90”)

### <Antioxidant (E)>

(E)-1: Hindered phenolic antioxidant (ADEKA Co., Ltd. “ADEKA STAB AO-60”)

### (Preparation of Heat Conduction Layer)

A composition obtained by kneading was put into an extrusion molding machine (Parker Co., Ltd., product name: HKS40-15 type extruder) and extruded into a flat plate shape with a width of 20 cm and a thickness of 1.5 mm to 1.6 mm to obtain a primary sheet. The obtained primary sheet was press punched using a 40 mm×150 mm die blade, and 61 of the punched sheets were layered and a spacer with a height of 80 mm was sandwiched so that the height of the sheet was 80 mm, and the pressure was applied for 30 minutes at 90° C. in the layering direction to obtain a layered body with 40 mm×150 mm×80 mm. Next, the side end face with 80 mm×150 mm of this layered body was sliced with a wood slicer to obtain a heat conduction layer with a thickness of 0.11 mm. The thickness of the heat conduction layer used in each of the Examples and Comparative examples was approximately the same.

### (Preparation of Heat Conduction Sheet)

A liquid heat conduction material having the composition shown below was prepared. The prepared liquid heat conduction material was applied to one or two main surfaces of the heat conduction layer obtained as described above, and the liquid component was uniformly spread with a special spatula to obtain a heat conduction sheet in which a liquid layer was formed on one or two main surfaces of the heat conduction layer.

### <Composition of Liquid Heat Conduction Materials>

First liquid heat conduction material (liquid material 1 in the table): AS-05A from Artic Silver, Inc. (containing liquid ester compound and silver particles, filler content 86% by mass, viscosity at 25° C. 145 Pa·s, thermal conductivity 9 W/(m·K))

Second liquid heat conduction material (liquid material 2 in the table): JunPus International Co., Ltd. JP-DX1 from Thermal Grizzly (containing liquid silicone compound and nano diamond, filler content 92% by mass, viscosity 3000 Pa·s at 25° C., thermal conductivity 16 W/(m·K))

Third liquid thermal conduction material (liquid material 3 in the table): Conductonaut from Thermal Grizzly (metal containing tin, gallium, and indium, viscosity 0.0021 Pa·s at 25° C., thermal conductivity 73 W/(m·K))

### Comparative Examples 1 and 2

The materials shown in Table 1 were kneaded, laminated, pressed, and sliced in the same manner as in Examples 1 to 4 to obtain the mixing ratio (volume %) shown in Table 1, to produce a heat conduction layer. In Comparative Example 1, a liquid layer was not formed, and the heat conduction layer was used as a heat conduction sheet. In Comparative Example 2, a heat conduction sheet with a liquid layer was obtained in the same manner as in each Example, except that a grease with a thermal conductivity of less than 5 W/(m·K) was used, as shown below.

Liquid material (Liquid material 4 in the table): Shin-Etsu Chemical's G-747 (containing liquid silicone compound and zinc oxide, filler content of 84% by mass, viscosity of 50 Pa·s at 25° C., thermal conductivity of 0.9 W/(m·K))

TABLE 1

| | | Volume % |
|---|---|---|
| Graphite particles (A) | (A)-1 | 33.8 |
| Liquid component (B) | (B)-1 | 28.4 |
| | (B)-2 | 13.1 |
| Acrylic acid ester polymer (C) | (C)-1 | 10.0 |
| Hot melt agent (D) | (D)-1 | 14.3 |
| Antioxidant (E) | (E)-1 | 0.4 |

| | |
|---|---|
| Total volume % | 100 |

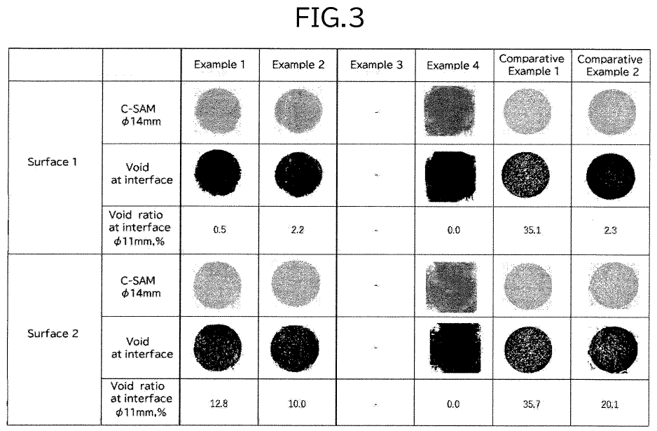

For the heat conduction sheets of Examples 1 to 4 and Comparative Examples 1 and 2, each evaluation was performed by the following method. The results are shown in Table 2 and FIG. 3.

### (Measurement of Thermal Resistance)

Thermal resistance was measured using a tabletop xenon flash analyzer (LFA 467 Hyper Flash). A sample with a three-layer structure was prepared by sandwiching a heat conduction sheet with a diameter of 14 mm between 1 mm copper plates. The sample preparation conditions were a temperature of 150° C. and a pressure of 0.14 MPa, the sample was pressured for 3 minutes. In addition, as a pretreatment for measurement, the copper surface was blackened using carbon spray, and then measured. From the three-layer structure, the thermal conductivity λ excluding the influence of the copper plates is obtained, and from the obtained thermal conductivity λ and the thickness t, the unit area (1 cm²) per thermal resistance value X (K·cm²/W) was calculated as follows.

$$X = ( 10 \times t ) / λ$$

$$t : Thickness ( mm ) of heat conduction sheet of Examples 1 to 4 or$$

$$Comparative Examples 1 to 2$$

$$λ : Thermal conductivity ( W / ( m \cdot K ) )$$

### (Evaluation of Void Ratio at Interface)

In the three-layer structure sample prepared by the method described in (Measurement of thermal resistance), the void ratio at the interface was evaluated as follows. Using an ultrasonic image diagnostic device (Insight-300, Insight Co., Ltd.), the adhesion state at the interface was observed under the condition of a reflection method, 35 MHz, gain level of 10 dB, and contrast threshold of 30% to 70%. Furthermore, the image is binarized using image analysis software (ImageJ) (specifically, 0 to 83 of the histogram are black and 84 to 255 are white), the ratio of the area of the non-adhered gas region with respect to the area of Φ11 mm (area of the measurement region; FIG. 3 shows an image of Φ14 mm) was calculated, and the void ratio (%) at the interface was calculated based on the following formula. In Example 3, the void ratio was not measured.

$$Void ratio ( \% ) at interface = 100 \times ( area of gas region / area of measurement region )$$

### (Evaluation of Thickness)

Compression was performed under the same conditions for the heat conduction sheet of each of Examples 1 to 4 and Comparative Example 1. Next, the maximum thickness of the heat conduction sheet after compression (“thickness after compression” in Table 2) was measured using a micrometer. The maximum thickness of the liquid layer was calculated by subtracting the maximum thickness of the heat conduction sheet including the liquid layer from the maximum thickness of the heat conduction sheet not including the liquid layer.

TABLE 2

| | | Example | Example | Example | Example | Comparative | Comparative |
|---|---|---|---|---|---|---|---|
| | | 1 | 2 | 3 | 4 | Example 1 | Example 2 |
| Liquid | — | 1 | 2 | 3 | 2 | — | 4 |
| material | | | | | | | |
| Amount of | mg | 5.0 | 4.7 | 56.0 | 22.4 | — | 4.5 |
| liquid layer | | | | | | | |
| Surface to be | — | One | One | Both | Both | none | One |
| applied | | surface | surface | surface | surface | | surface |
| Thickness | μm | 102 | 104 | 119 | 131 | 101 | — |
| after | | | | | | | |
| compression | | | | | | | |
| Maximum | μm | 1 | 3 | 18 | 30 | — | — |
| thickness of | | | | | | | |
| liquid layer | | | | | | | |
| Thermal | K · cm²/W | 0.112 | 0.127 | 0.086 | 0.135 | 0.143 | 0.160 |
| resistance | | | | | | | |
| Change ratio | % | −22% | −11% | −40% | −6% | — | +12% |
| of thermal | | | | | | | |
| resistance (to | | | | | | | |
| Comparative | | | | | | | |
| Example 1) | | | | | | | |
| Void ratio at | % | 0.5 | 2.2 | — | 0 | 35.1 | 2.3 |
| interface | | | | | | | |
| (Surface 1) | | | | | | | |
| Void ratio at | % | 12.8 | 10.0 | — | 0 | 35.7 | 20.1 |
| interface | | | | | | | |
| (Surface 2) | | | | | | | |

It was confirmed that the thermal resistance could be reduced in Examples 1 to 4, in which liquid materials having a thermal conductivity of 5 W/(m·K) or more were used, compared to Comparative Example 1, in which a liquid material was not used and Comparative Example 2, in which a liquid material having a thermal conductivity of less than 5 W/(m·K) was used.

The entire contents of the disclosures by PCT/JP2022/028528 are incorporated herein by reference.

All publications, patent applications, and technical standards mentioned in the present specification are herein incorporated by reference to the same extent as if each individual publication, patent application, and technical standard were specifically and individually indicated to be incorporated by reference.

1. A liquid heat conduction material having a thermal conductivity of 5 W/(m·K) or more, for forming a liquid layer by applying the material to at least a part of a heat conduction layer containing heat conductive particles.

2. The liquid heat conduction material according to claim 1, wherein the material comprises a heat conductive filler and a resin component.

3. The liquid heat conduction material according to claim 2, wherein a particle size of the heat conductive filler is from 0.1 μm to 50 μm.

4. The liquid heat conduction material according to claim 2, wherein the resin component comprises a thermosetting resin component.

5. The liquid heat conduction material according to claim 1, wherein a viscosity at 25° C. is 4000 Pa·s or less.

6. The liquid heat conduction material according to claim 2, wherein a content ratio of the heat conductive filler is from 70% by mass to 98% by mass with respect to a total amount of the liquid conduction material.

7. The liquid heat conduction material according to claim 2, wherein a total content ratio of the heat conductive filler and the resin component is from 80% by mass to 100% by mass with respect to a total amount of the liquid heat conduction material.

8. A heat conduction sheet, comprising:
a heat conduction layer including a heat conduction material containing heat conductive particles, and
a liquid layer which is located on at least a part of a main surface of the heat conduction layer and contains a first liquid heat conduction material which is the liquid heat conduction material according to any one of claims 1 to 5, or a second liquid heat conduction material which is a liquid heat conduction material containing a metal component.

9. The heat conduction sheet according to claim 8,
wherein the heat conductive particles includes at least one kind of graphite particles (A) selected from the group consisting of scale-like particles, ellipsoidal particles and rod-like particles,
wherein in a case of scale-like particles, a plane direction of the particle is oriented in a thickness direction of the heat conduction layer, and in a case of ellipsoidal particles or rod-like particles, a long axis direction of the particle is oriented in the thickness direction of the heat conduction layer.

10. The heat conduction sheet according to claim 8, wherein a maximum thickness of the liquid layer is from 0.5 μm to 20 μm.

11. The heat conduction sheet according to claim 8, wherein the liquid layer contains the first liquid heat conduction material and the liquid layer is curable by heating.

12. The heat conduction sheet according to claim 8, wherein the heat conduction layer contain a liquid component (B), and the liquid component (B) contains polybutene.

13. The heat conduction sheet according to claim 8, wherein a content ratio of the liquid component (B) is from 10% by volume to 55% by volume.

14. The heat conduction sheet according to claim 8, wherein the heat conduction layer contains an acrylic ester polymer (C).

15. The heat conduction sheet according to claim 8, wherein the heat conduction layer contains a hot melt agent (D).
